(19) United States
(12) Patent Application Publication
(10) Pub. No.: US 2024/0106401 A1
(43) Pub. Date: Mar. 28, 2024

(54) MEASUREMENT SYSTEM, RELATED INTEGRATED CIRCUIT AND METHOD

(71) Applicant: STMicroelectronics S.r.l., Agrate Brianza (MB) (IT)

(72) Inventors: Germano NICOLLINI, Piacenza (IT); Michele VAIANA, San Giovanni La Punta (CT) (IT)

(73) Assignee: STMicroelectronics S.r.l., Agrate Brianza (MB) (IT)

(21) Appl. No.: 18/369,583

(22) Filed: Sep. 18, 2023

(30) Foreign Application Priority Data
Sep. 19, 2022 (IT) 102022000019113

(51) Int. Cl. H03F 3/45; H03F 1/26

(52) U.S. Cl. CPC H03F 3/45475; H03F 1/26; H03F 3/45273; H03F 2200/261

(57) ABSTRACT

A measurement system, featuring first and second capacitances, and switching, control, and measurement circuits, charges/discharges the capacitances during normal operation. The switching and control circuits periodically connect a first terminal of the first capacitance to a first voltage and a reference voltage, and a first terminal of the second capacitance to a second voltage and the reference voltage. The second terminal of the first capacitance and the second terminal of the second capacitance are connected to the input terminals of the differential integrator, the charge difference between the capacitances being transferred to the differential integrator. A comparator triggers when the output signal of the differential integrator exceeds the hysteresis threshold of the comparator. Two decoupling capacitances are connected between the input of the comparator and the output of the differential integrator, and two reset phases are used to store various disturbances to these decoupling capacitances, improving precision.

### PRIORITY CLAIM

This application claims the priority benefit of Italian Application for Patent No. 102022000019113, filed on Sep. 19, 2022, the content of which is hereby incorporated by reference in its entirety to the maximum extent allowable by law.

### TECHNICAL FIELD

The embodiments of the present description refer measurement systems, such as capacitive sensors.

### BACKGROUND

Capacitive sensors are commonly used. For example, such capacitive sensor may have a high resolution, low complexity and low temperature-dependency. For example, such capacitive sensors may be used in microelectromechanical systems (MEMS) based sensors, such as accelerometers, position sensors, pressure sensors, and moisture sensors. Recently, such capacitive sensors have also been used for Laboratory on a Chip (LoC) applications, e.g., for DNA protein interaction quantification, cellular monitoring, bio-particle detection, organic solvent monitoring, sensing of droplet parameters, bacteria detection, etc.

In general, a capacitive sensor comprises at least one pair of sensing electrodes that are connected to an interface readout circuit.

For example, FIG. 1 shows a typical LoC application, wherein two electrodes 100 and 102 implemented with a conductive material are arranged on an integrated circuit 20. In a capacitive sensor, the electrodes 100 and 102 are connected to an interface circuit, e.g., implemented within the integrated circuit 20, which is configured to generate an analog or digital signal by measuring a value being indicative of the capacitance value between the electrodes 100 and 102.

Accordingly, in case the physical, biological and/or chemical properties of a sample 104 in the vicinity of the electrodes 100 and 102 influence the capacitance of the capacitor formed by the electrodes 100 and 102, a processing circuit, e.g., implemented within the integrated circuit 20, may be configured to provide an estimate of the physical, biological and/or chemical properties of the sample 104 as a function of the measured capacitance value.

In this respect Complementary Metal-Oxide-Semiconductor (CMOS) technology offers great advantages for the development of capacitive sensors, e.g., because it permits implementing of highly integrated circuits with low costs. This also permits achievement of a higher sensitivity and a rapid detection, and integration of the electrical readout circuit and/or the sensing electrodes on a single chip 20. Those of skill in the art will appreciate that various CMOS capacitive sensing techniques have been proposed in literature for different LoC applications. One of the most commonly used techniques is the charge-based capacitance measurement (CBCM). For example, the CBCM technique is described in document Chen, et al., “An On-Chip, Attofarad Interconnect Charge-Based Capacitance Measurement (CBCM) Technique”, International Electron Devices Meeting (IEDM) 1996, or United States Patent Publication No. 2003/0218473), the contents of each of which are incorporated herein by reference.

FIG. 2 shows an example of an interface circuit 30 according to the CBCM technique.

As mentioned before, the electrodes 100 and 102 form a sense capacitance/capacitor Cₛ, wherein the capacitance value of the sense capacitance Cₛ is usually indicative of the physical, biological and/or chemical properties of a sample 104 in the vicinity of the electrodes 100 and 102.

Specifically, in the example considered, the current path of a first electronic switch M₄, such as a transistor, such as an n-channel Field-effect transistor (FET), such as an n-channel Metal-Oxide-Semiconductor (MOS) FET, is connected (e.g., directly) in parallel with the sense capacitance C_{S}, i.e., the electronic switch M₄ is connected between the electrodes 100 and 102, and is thus configured to selectively short-circuit the sense capacitance C_{S} as a function of a control signal Φ₂ received at a control terminal of the electronic switch M₄, e.g., the gate terminal of a corresponding FET.

Moreover, the interface circuit comprises a second electronic switch M₂, such as a transistor, such as an p-channel Field-effect transistor (FET), such as an p-channel MOSFET, configured to selectively connect the sense capacitance C_{S} to a supply voltage VDD as a function of a control signal Φ₁ received at a control terminal of the electronic switch M₂, e.g., the gate terminal of a corresponding FET. For example, in the example considered, the electrode 102 of the capacitance C_{S} is connected to a first reference voltage, e.g., ground GND, and the electrode 100 is connected via the electronic switch M₂ to a second reference voltage, e.g., a supply voltage VDD of the integrated circuit 20. Accordingly, when the electronic switch M₄ is opened, the electronic switch M₂ may be used to selectively charge the sense capacitance C_{S}. Accordingly, a control circuit (CC) 36 may be configured to generate the control signals Φ₁ and Φ₂ in order to selectively charge and discharge the sense capacitance C_{S}.

For example, as shown in FIG. 3, typically, the control circuit 36 is configured to generate the control signals Φ₁ and Φ₂ according to switching cycles having a duration/period T_{S}. Specifically, typically, each switching cycle T_{S} comprises a sequence of the following four phases:
a phase Δt₁, wherein both electronic switches M₂ and M₄ are opened, e.g., by setting the signal Φ₁ to high and the signal Φ₂ to low;
a phase Δt₂, wherein the electronic switch M₂ is opened and the electronic switch M₄ is closed, e.g., by setting the signal Φ₁ to high and the signal Φ₂ to high, whereby the capacitance C_{S} discharges trough the electronic switch M₄ to ground;
a phase Δt₂, wherein both electronic switches M₂ and M₄ are opened, e.g., by setting the signal Φ₁ to high and the signal Φ₂ to low; and
a phase Δt₄, wherein the electronic switch M₂ is closed and the electronic switch M₄ is opened, e.g., by setting the signal Φ₁ to low and the signal Φ₂ to low, whereby the sense capacitance C_{S} is connected to the supply voltage VDD and is charged with a current i_{S}.

Accordingly, the phase Δt₂ is used to reset the charge of the capacitance C_{S} and the phase Δt₄ is used to charge the capacitance C_{S}. Generally, the phases Δt₁ and Δt₃ are purely optional and are used to avoid the electronic switches M₂ and M₄ generating a short-circuit by connecting the supply voltage VDD to ground.

Accordingly, as shown in FIG. 2, the interface circuit 30 may comprise a measurement circuit 34 configured to measure the charge or discharge current i_{S} flowing through the capacitance C_{S}. For example, in the example considered, the measurement circuit 34 comprises a current sensor 340 connected between the electronic switch M₂ and the supply voltage VDD, thereby monitoring the charge current.

Typically, the CBCM technique uses also a second branch, which comprises a reference capacitance C_{R}. Typically, the reference capacitance C_{R} has the same physical structure as the sense capacitance C_{S}, but is not exposed to the sample 104. For example, in the absence of a sample 104, the capacitance values C_{S} and C_{R} typically correspond, i.e., C_{S}=C_{R}. Conversely, in the presence of a sample 104, the capacitance value of the sense capacitance C_{S} varies and usually increases, i.e., C_{S}>C_{R}.

Accordingly, in this case, the second branch comprises: a first electronic switch M₃, such as an n-channel FET, such as a n-channel MOSFET, configured to selectively short-circuit the reference capacitance C_{R}, and a second electronic switch M₁, such as a p-channel FET, such as a p-channel MOSFET, configured to selectively connect the reference capacitance C_{R} to the supply voltage VDD.

Typically, the electronic switch M₃ is driven via the control signal (2 and the electronic switch M₁ is driven via the control signal Φ₁. In fact, as shown in FIG. 3, in this case the reference capacitance C_{R} is reset during the phase Δt₂ and is charged during the phase Δt₄, thereby generating a current flow i_{R}. Accordingly, also in this case the interface circuit 30 may comprise a current sensor 342 configured to measure the charge or discharge current i_{R} flowing through the capacitance C_{R}. For example, in the embodiment considered, the current sensor 342 is connected between the electronic switch M₁ and the supply voltage VDD, thereby monitoring the charge current.

Accordingly, in the example considered, the interface circuit 30 comprises a first half-bridge implemented with the electronic switches M₂ and M₄, wherein the first half-bridge is configured to selectively apply a first reference voltage (usually the supply voltage VDD) or a second reference voltage (usually ground GND) to a first terminal/electrode 100 of the sense capacitance C_{S}, wherein the second terminal/electrode 102 of the sense capacitance C_{S} is connected to the second reference voltage (usually ground GND). Moreover, the interface circuit 30 comprises a second half-bridge implemented with the electronic switches M₁ and M₃, wherein the second half-bridge is configured to selectively apply the first reference voltage (usually the supply voltage VDD) or the second reference voltage (usually ground GND) to a first terminal/electrode of the reference capacitance C_{R} wherein the second terminal/electrode of the reference capacitance C_{R} is connected to the second reference voltage (usually ground GND). The two half-bridges are identified as a CBCM cell 32.

For example, when using the CMOS technology, the electronic switches M₃ and M₄ are usually implemented with n-channel MOSFETs and the electronic switches M₁ and M₂ are usually implemented with p-channel MOSFETs. In this case, the source terminals of the n-channel FETs M₃ and M₄ are connected to the second reference voltage (e.g., ground GND), the source terminals of the p-channel FETs M₁ and M₂ are connected to the first reference voltage (e.g., VDD), the drain terminals of the n-channel FET M₄ and the p-channel FET M₂ are connected to the first terminal/electrode of the sense capacitance C_{S}, and the drain terminals of the n-channel FET M₃ and the p-channel FET M₁ are connected to the first terminal/electrode of the reference capacitance C_{R}.

Accordingly, in the CBMS technique, the properties of the sample 104 are usually evaluated based on the capacitive difference ΔC between the capacitances C_{S} and C_{R}, i.e., ΔC=C_{S}−C_{R}. For example, for this purpose, the measurement circuit 32 should be configured to generate a signal indicative of the difference Δi between the (charge or discharge) currents i_{S} and i_{R}, i.e., Δi=i_{S}−i_{R}.

In this respect, the previously cited document by Chen, et al., affirms that this technique has an intrinsic estimated sensitivity of about 10 aF. Accordingly, a major technical problem resides in the design and implementation of the measurement/readout circuit of the CBCM cell 32 that does not degrade or has only a minor impact on this performance.

FIG. 4 shows a first example of a measurement circuit of the CBCM cell 32 configured to generate a signal indicative of the difference Δi between the currents i_{S} and i_{R}. For example, such a solution is disclosed in Forouhi, et al., “Toward High Throughput Core-CBCM CMOS Capacitive Sensors for Life Science Applications: A Novel Current-Mode for High Dynamic Range Circuitry”, Sensors 2018, the contents of which are incorporated herein by reference.

Specifically, in the example considered, the measurement circuit of the CBCM cell 32 comprises a first current mirror 3400, e.g., implemented with two p-channel FETs, configured to generate a current i_{S}′ by mirroring the (charge) current i_{S} provided to the CBCM cell 32. This mirrored current i_{S}′ is used to charge a first capacitance Cᵢₙₜ₊, which essentially operates as an integrator configured to convert the current i_{S}′(t) into a voltage. Similarly, the measurement circuit of the CBCM cell 32 comprises a second current mirror 3410, e.g., implemented with two p-channel FETs, configured to generate a current i_{R}′ by mirroring the (charge) current i_{R} provided to the CBCM cell 32. This mirrored current i_{R}′ is used to charge a second capacitance Cᵢₙₜ₋, which essentially operates as an integrator configured to convert the current i_{R}′(t) into a voltage.

Accordingly, in the example considered, a differential amplifier 3420 may be used to generate a signal, e.g., a voltage Vₒᵤₜ, by amplifying the difference between the voltage at the capacitance Cᵢₙₜ₊ and the voltage at the capacitance Cᵢₙₜ₋. For example, in the example considered, the voltage at the capacitance Cᵢₙₜ₊ is connected to the positive input terminal of the differential amplifier 3420 and the voltage at the capacitance Cᵢₙₜ₋ is connected to the negative input terminal of the differential amplifier 3420. The capacitances Cᵢₙₜ₊ and Cᵢₙₜ₋ have the same capacitance value.

In this case, the measurement circuit 34 may also comprise electronic switches 3402 and 3412 in order to selectively discharge the capacitances Cᵢₙₜ₊ and Cᵢₙₜ₋, e.g., as a function of a reset signal RST. In fact, the circuit of FIG. 4 permits execution of a plurality of the switching cycles T_{S} shown in FIG. 3, during each of which the current pulse in the currents i_{S} and i_{R} are transferred to the capacitances Cᵢₙₜ₊ and Cᵢₙₜ₋, respectively.

Accordingly, in the example considered, the capacitances C_{S} and C_{R} are not charged directly with voltage VDD, but rather with a voltage (VDD−Vₜₕₚ), where Vₜₕₚ corresponds to the threshold of the input FETs of the current mirrors 3400 and 3410, i.e., the voltage ΔV at the input of the differential amplifier 3420 may be approximated with the following equation after a given number N of switching cycles:

$$Δ V = N \frac{Δ C}{{C}_{i n t}} ( VDD - {V}_{thp} ) \qquad ( 1 )$$

Accordingly, a first drawback relates to the fact the output Vₒᵤₜ is also a function of the threshold Vₜₕₚ, which depends on temperature and process spread variations. Moreover, in this approach, to achieve a higher sensitivity, high voltages across the integrating capacitors Cᵢₙₜ₊ and Cᵢₙₜ₋ are required. However, this situation may push the differential amplifier 3420 to a nonlinear region, and thus limits the resolution of the sensor circuit. To mitigate this second problem, the previously cited article by Forouhi, et al., also discloses an alternative approach, which is shown in FIG. 5.

Specifically, in the example shown in FIG. 5, the current mirrors 3400 and 3410 are again configured to generate mirrored currents i_{S}′ and i_{R}′, respectively.

However, in this case a further current mirror 3430, e.g., implemented with n-channel FETs, is used to generate a further mirrored current i_{R}″ by mirroring the current i_{R}′. Specifically, in the example considered, the output of the current mirror 3400 is connected in series with a capacitance Cᵢₙₜ. Conversely, the output of the current mirror 3430 is connected in parallel with the capacitance Cᵢₙₜ. Accordingly, in the example considered, the capacitance Cᵢₙₜ is indeed charged with a current ix corresponding to the difference between the currents i_{S}′ and i_{R}″, i.e., i_{X}=i_{S}′−i_{R}″.

Accordingly, also the circuit of FIG. 5 permits execute of a plurality of the switching cycles shown in FIG. 3, during each of which the current pulse in the current i_{X} is transferred to the capacitances Cᵢₙₜ. Specifically, by using a current mirror 3430 with a mirroring ratio of one, and current mirrors 3400 and 3410 with a mirroring ratio of K, the voltage Vₒᵤₜ at the capacitance Cᵢₙₜ may be approximated with the following equation after a given number N of switching cycles:

$${V}_{o u t} = \frac{Δ C}{{C}_{i n t}} ( VDD - {V}_{t h p} ) \qquad ( 2 )$$

Generally, the previously cited document also discloses a respective differential version of the circuit shown in FIG. 5.

Unfortunately, the approach shown in FIG. 5 is based on several current mirrors having current gains, whose offsets and mismatches severely impact the sensing of the capacitance difference ΔC. Conversely, this was only a minor problem in the solution shown in FIG. 4, because current mirrors without any gain may be used. Considering the foregoing, there is a need in the art for various embodiments to provide a measurement system, which overcomes the problems outlined in the foregoing.

### SUMMARY

According to one or more embodiments, a measurement system is provided. Embodiments moreover concern a related integrated circuit and method.

As mentioned before, various embodiments of the present disclosure relate to a measurement system. In various embodiments, the measurement system includes a first capacitance and a second capacitance. The measurement system includes moreover a switching circuit configured to receive a first and a second control signal. In response to determining that the first control signal is asserted, the switching circuit connects a first terminal of the first capacitance to a first voltage and a first terminal of the second capacitance to a second voltage. Moreover, in response to determining that the second control signal is asserted, the switching circuit connects the first terminal of the first capacitance and the first terminal of the second capacitance to a reference voltage, e.g., ground.

In various embodiments, a control circuit is configured to generate the first and second control signals according to switching cycles comprising four intervals. Specifically, for a first interval, the control circuit de-asserts the first and second control signals. For a following second interval, the control circuit de-asserts the first control signal and asserts the second control signal, thereby connecting the first capacitance to the first voltage and the second capacitance to the second voltage. For a following third interval, the control circuit de-asserts the first and the second control signal. Finally, for a following fourth interval, the control circuit asserts the first control signal and de-asserts the second control signal, thereby connecting the first capacitance and the second capacitance to the reference voltage.

In various embodiments, the measurement system also includes a measurement circuit, which in turn includes a differential integrator and a comparator with hysteresis.

In various embodiments, the differential integrator includes a differential operational amplifier, a first integration capacitance and a second integration capacitance. Specifically, in various embodiments, an inverting input of the differential operational amplifier is connected to a second terminal of the first capacitance and a non-inverting input of the differential operational amplifier is connected to a second terminal of the second capacitance. A first terminal of the first integration capacitance is connected to the inverting input of the differential operational amplifier and a second terminal of the first integration capacitance is connected via a first electronic switch to a positive output terminal of the differential operational amplifier, wherein the second terminal of the first integration capacitance represents a first output node of the differential integrator. Similarly, a first terminal of the second integration capacitance is connected to the non-inverting input of the differential operational amplifier and a second terminal of the second integration capacitance is connected via a second electronic switch to a negative output terminal of the differential operational amplifier, wherein the second terminal of the second integration capacitance represents a second output node of the differential integrator. In various embodiments, the differential integrator also includes a third electronic switch connected between the inverting input of the differential operational amplifier and the positive output terminal of the operational amplifier, and a fourth electronic switch connected between the non-inverting input of the differential operational amplifier and the negative output terminal of the operational amplifier.

In various embodiments, the comparator with hysteresis is configured to, in response to determining that a voltage applied to a negative input terminal of the comparator with hysteresis exceeds a voltage applied to a positive input terminal of the comparator with hysteresis plus a hysteresis threshold, set a first output terminal of the comparator with hysteresis to high and a second output terminal of the comparator with hysteresis to low. Moreover, in various embodiments the comparator with hysteresis includes a fifth electronic switch connected between the negative input of the comparator with hysteresis and the second output terminal of the comparator with hysteresis, and a sixth electronic switch connected between the positive input of the comparator with hysteresis and the first output terminal of the comparator with hysteresis.

In various embodiments, a first decoupling capacitance is connected between the negative input of the comparator with hysteresis and the first output node of the differential integrator, and a second decoupling capacitance connected between the positive input of the comparator with hysteresis and the second output node of the differential integrator.

Specifically, the measurement system is configured to manage a normal operation phase and a reset phase.

Specifically, during the normal operation phase, the measurement system is configured to close the first electronic switch and the second electronic switch, in response to determining that the second control signal is asserted. Conversely, the measurement system is configured to open the first electronic switch and the second electronic switch in response to determining that the second control signal is de-asserted. Moreover, the measurement system is configured to close the third electronic switch and the fourth electronic switch in response to determining that the first control signal is asserted, and open the third electronic switch and the fourth electronic switch in response to determining that the first control signal is de-asserted. Thus, when the first control signal is de-asserted and the second control signal is asserted, the first integration capacitance and the second integration capacitance are connected into the feedback paths of the differential operational amplifier, thereby permitting a charge transfer from the first and second capacitances to the first and second integration capacitances. For example, the first and second capacitances have a different charge when the first voltage and the second voltage correspond to a common voltage, but the first capacitance corresponds to a sense capacitance and the second capacitance corresponds to a reference capacitance. In fact, in this case, the voltage between the first and second output nodes of the differential integrator is indicative of the difference between the capacitances of the sense capacitance and the reference capacitance. Conversely, when the first capacitance and the second capacitance have the same capacitance value, the voltage between the first and second output nodes of the differential integrator is indicative of the difference between the first voltage and the second voltage. During the normal operation phase, the comparator with hysteresis is thus operative, i.e., the fifth electronic switch and the sixth electronic switch are opened.

In various embodiments, the measurement system also monitors a reset request signal during the normal operation phase and, in response to determining that the reset request signal indicates a reset request, the measurement system starts the reset phase. For example, in various embodiments, the measurement system is configured to assert the reset request signal after a given maximum number of the switching cycles, and/or in response to determining that the first output terminal of the comparator with hysteresis is set to high and/or the second output terminal of the comparator with hysteresis is set to low.

In various embodiments, during the reset phase, the measurement system executes at least two sub-phases. Specifically, for a first reset interval, the measurement system closes the first, second, third, fourth, fifth and sixth electronic switches. Conversely, for a following second reset interval, the measurement system opens the third and fourth electronic switches and keeps closed the first, second, fifth and sixth electronic switches. Finally, at the end of second phase, the measurement system starts again the normal operation phase. Specifically, as will be described in greater detail in the following, in various embodiments, apart from resetting the integration capacitances and the comparator with hysteresis, the offsets and most of the flicker noise of the differential operational amplifier and the comparator with hysteresis may be stored to the decoupling capacitance during the first reset interval. Moreover, during the second reset interval, also the charge-injection and clock-feedthrough of the third and fourth electronic switches may be stored to the decoupling capacitance.

For example, in order to implement the described reset phase, the differential integrator may receive a first reset signal, and the third electronic switch and fourth electronic switch may be configured to be closed in response to determining that the first control signal is asserted or the first reset signal is asserted. Moreover, the comparator with hysteresis may be configured to receive a second reset signal, wherein the fifth electronic switch and the sixth electronic switch are configured to be closed in response to determining that the second reset signal is asserted. Accordingly, in this case, the measurement system may be configured to, while the control circuit asserts the second control signal, assert the first reset signal and the second reset signal for the first reset interval, and de-assert the first reset signal and assert the second reset signal for the second reset interval. For example, for this purpose the measurement system may include a delay circuit configured to generate the second reset signal by delaying the first reset signal.

### BRIEF DESCRIPTION OF THE DRAWINGS

The embodiments of the present disclosure will now be described with reference to the annexed plates of drawings, which are provided purely to way of non-limiting example and in which:

FIG. 1 shows an example of a known capacitive sensor;

FIG. 2 shows an example of a known measurement system for capacitive sensors;

FIG. 3 shows waveforms of the measurement system of FIG. 2;

FIGS. 4 and 5 show possible implementations of the measurement system of FIG. 2;

FIG. 6 shows an embodiment of a measurement system according to the present disclosure;

FIG. 7 shows an embodiment of a measurement circuit of the measurement system of FIG. 6;

FIGS. 8A, 8B and 8C show embodiments of switching circuits of the measurement system of FIG. 6;

FIG. 9 shows an embodiment of waveforms of the measurement system of FIG. 6;

FIG. 10 shows a detail of the measurement circuit of FIG. 7; and

FIGS. 11, 12, 13 and 14 show further embodiments of switching circuits of the measurement system of FIG. 6.

### DETAILED DESCRIPTION

In the ensuing description, various specific details are illustrated aimed at enabling an in-depth understanding of the embodiments. The embodiments may be provided without one or more of the specific details, or with other methods, components, materials, etc. In other cases, known structures, materials, or operations are not shown or described in detail so that various aspects of the embodiments will not be obscured.

Reference to “an embodiment” or “one embodiment” in the framework of this description is meant to indicate that a particular configuration, structure, or characteristic described in relation to the embodiment is comprised in at least one embodiment. Hence, phrases such as “in an embodiment”, “in one embodiment”, or the like that may be present in various points of this description do not necessarily refer to one and the same embodiment. Moreover, particular conformations, structures, or characteristics may be combined in any adequate way in one or more embodiments.

The references used herein are provided for convenience and hence do not define the sphere of protection or the scope of the embodiments.

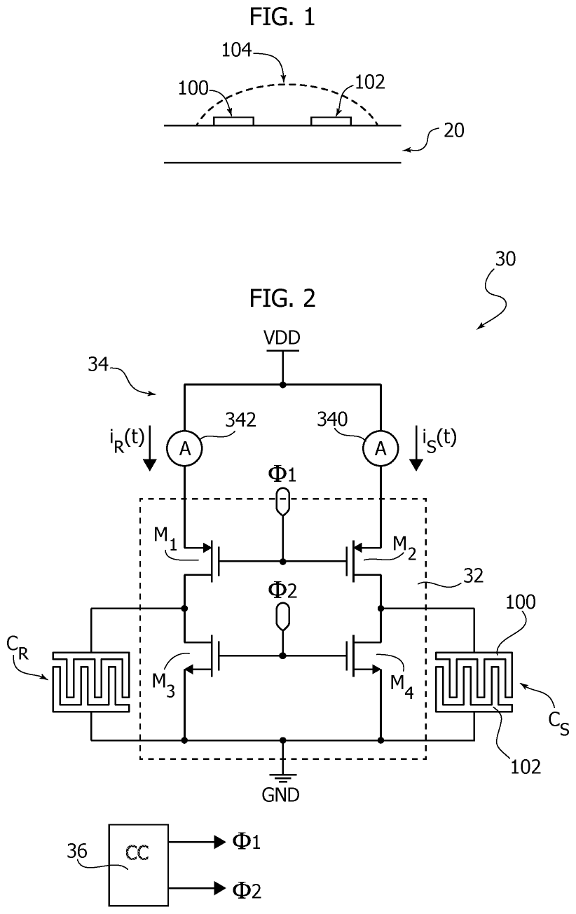

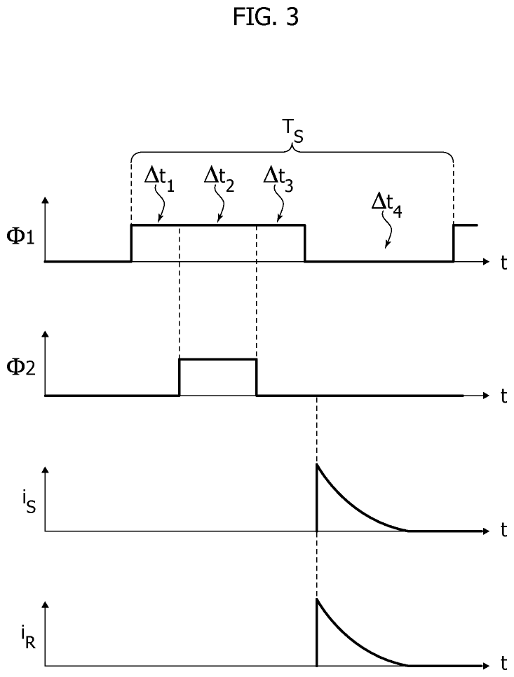

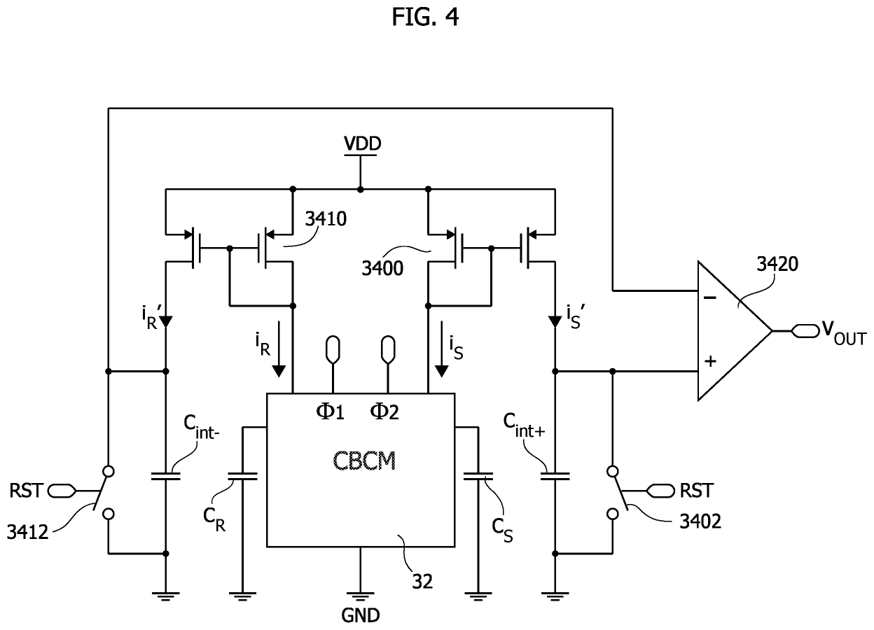

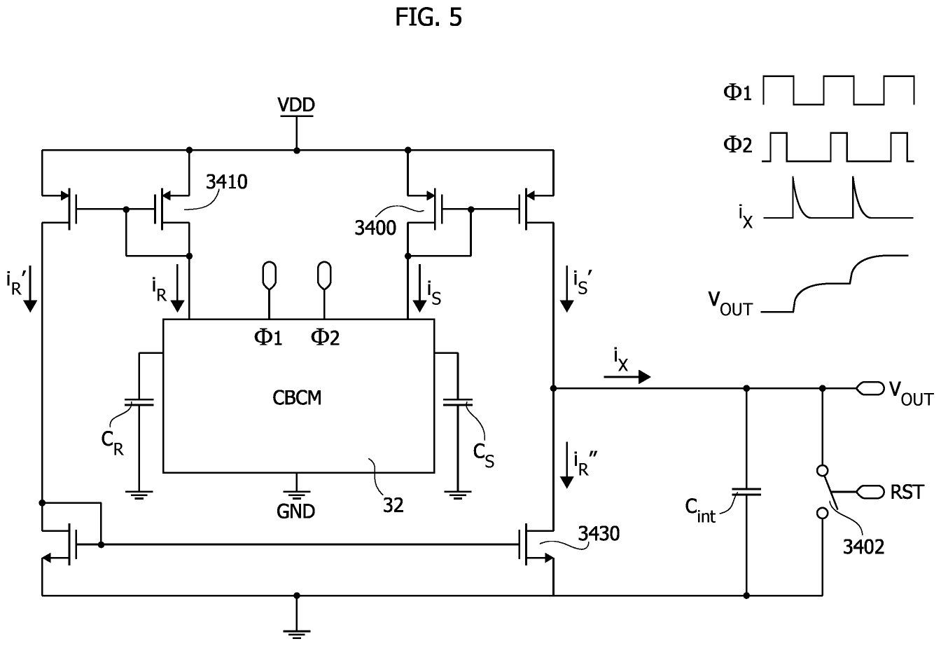

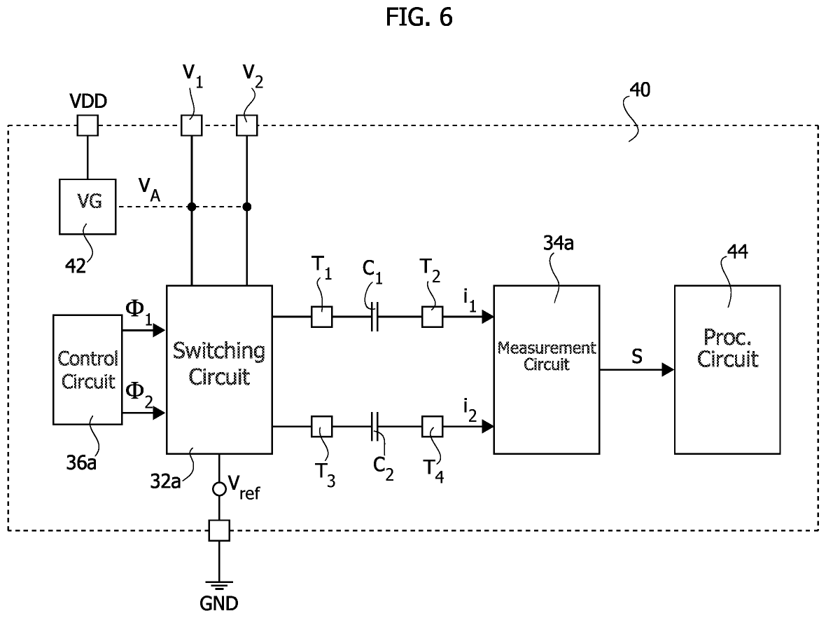

In FIGS. 6 to 14 described below, parts, elements or components that have already been described with reference to FIGS. 1 to 5 are designated by the same references used previously in these figures. The description of these elements has already been made and will not be repeated in what follows in order not to burden the present detailed description.

As mentioned before, various embodiments of the present disclosure relate to a measurement system.

FIG. 6 shows an embodiment of a measurement system according to the present disclosure. For example, such a measurement system may be integrated in an integrated circuit 40. In the embodiment considered, the measurement system comprises a switching circuit 32a with three terminals: a first terminal configured to be connected to a reference voltage V_{ref}, such as ground GND; a second terminal configured to be connected to a first voltage V₁, wherein the first voltage is greater than the reference voltage V_{ref}/ground GND; and a third terminal configured to be connected to a second voltage V₂, wherein the second voltage is greater than the reference voltage V_{ref}/ground GND.

As will be described in greater detail in the following, in various embodiments, the voltages V₁ and V₂ may also correspond to the same voltage, indicated in the following as voltage V_{A}. For example, in various embodiments, the measurement system may comprise a voltage generator (VG) 42 configured to receive a supply voltage VDD, e.g., via a pad/pin of the integrated circuit 40, and generate the voltage V_{A} based on this supply voltage VDD.

In the embodiment considered, the measurement system has two associated capacitances C₁ and C₂. These capacitances are integrated in the measurement system for best matching. In general, the capacitance has two terminals T₁ and T₂, and the capacitance has two terminals T₃ and T₄.

Specifically, in various embodiments, the switching circuit 32a receives a first control signal Φ₁ and a second control signal Φ₂. For example, the control signal Φ₁ and Φ₂ may be generated by a control circuit 36a of the measurement system. Specifically, similar to the previous description, the control circuit 36a may be configured to generate the control signals Φ₁ and Φ₂ according to switching cycles having a duration/period T_{S}, wherein each switching cycle T_{S} comprises a sequence of the following four phases: a phase Δt₁, wherein the signals Φ₁ and Φ₂ are de-asserted; a phase Δt₂, wherein the signal Φ₁ is de-asserted and the signal Φ₂ is asserted; a phase Δt₃, wherein the signals Φ₁ and Φ₂ are de-asserted; and a phase Δt₄, wherein the signal Φ₁ is asserted and the signal Φ₂ is de-asserted.

For example, in various embodiments, the switching circuit 32a is configured to:
in response to determining that the signal Φ₁ is asserted and the signal Φ₂ is de-asserted, connect the terminal T₁ to the voltage V₁ and the terminal T₃ to the voltage V₂;
in response to determining that the signal Φ₁ is de-asserted and the signal Φ₂ is asserted, connect the terminals T₁ and T₃ to the reference voltage V_{ref}/ground GND; and
in response to determining that the signals Φ₁ and Φ₂ are de-asserted, put the terminals T₁ and T₃ in a high-impedance state, e.g., by disconnecting the terminals T₁ and T₃.

Accordingly, in various embodiments, the switching circuit 32a is configured to apply the reference voltage V_{ref}, or the voltages V₁ and V₂, to the terminals T₁ and T₃ of the capacitances C₁ and C₂, respectively.

Accordingly, in various embodiments, a measurement circuit 34a is configured to monitor a current i₁ flowing through the capacitance C₁ and a current i₂ flowing through the capacitance C₂.

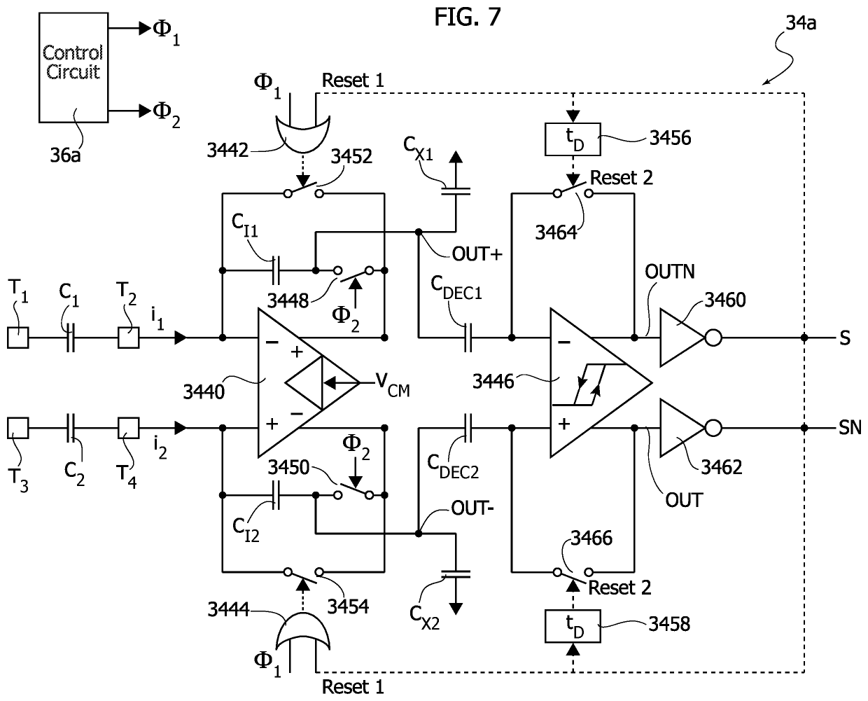

FIG. 7 shows an embodiment of a measurement circuit 34a according to the present disclosure.

Specifically, in the embodiment considered, the measurement circuit 34a is implemented with a switched capacitor (SC) differential integrator. Specifically, in the embodiment considered, the differential integrator comprises a differential operational amplifier 3440, wherein the inverting/negative input terminal of the operational amplifier 3440 is connected (e.g., directly) to the terminal T₂ of the capacitance C₁, and the non-inverting/positive input terminal of the operational amplifier 3440 is connected (e.g., directly) to the terminal T₄ of the capacitance C₂. Specifically, in order to implement a differential integrator configured to integrate the difference Δi between the currents i₁ and i₂ during the discharge phase, i.e., when the signal Φ₂ is asserted, the differential integrator comprises:
a first integration capacitance C_{I1}, wherein a first terminal of the integration capacitance C_{I1} is connected (e.g., directly) to the inverting/negative input terminal of the operational amplifier 3440 and a second terminal of the first integration capacitance C_{I1} is connected (e.g., directly) via the current path of an electronic switch 3448 to the positive output terminal of the operational amplifier 3440;
a second integration capacitance C_{I2}, wherein a first terminal of the integration capacitance C_{I2} is connected (e.g., directly) to the non-inverting/positive input terminal of the operational amplifier 3440 and a second terminal of the second integration capacitance C_{I2} is connected (e.g., directly) via the current path of an electronic switch 3450 to the negative output terminal of the operational amplifier 3440.

Specifically, the electronic switches 3448 and 3450 are driven by the signal Φ₂, and are closed when the signal Φ₂ is asserted. Accordingly, in the embodiment considered, the electronic switches 3448 and 3450 are closed when the signal Φ₂ is asserted, i.e., during the discharge phase, thereby connecting the integration capacitances C_{I1} and C_{I2} into the feedback paths of the operation amplifier 3440. In various embodiments, the first and second integration capacitance C_{I1} and C_{I2} have the same capacitance C_{I}. For example, the capacitances C_{I1} and C_{I2} may be implemented with internal capacitors for best matching with the capacitances C₁ and C₂.

Moreover, in the embodiment considered, the current path of an electronic switch 3452 is connected (e.g., directly) between the inverting/negative input terminal of the operational amplifier 3440 and the positive output terminal of the operational amplifier 3440, and the current path of an electronic switch 3454 is connected (e.g., directly) between the non-inverting/positive input terminal of the operational amplifier 3440 and the negative output terminal of the operational amplifier 3440. Specifically, the electronic switches 3452 and 3454 are driven by the signal Φ₁, and are closed when the signal Φ₁ is asserted. Accordingly, the electronic switches 3452 and 3454 are closed when the signal Φ₁ is asserted, i.e., during the charge phase, thereby short-circuiting the feedback paths of the operation amplifier 3440.

As schematically shown in FIG. 7, the differential operational amplifier 3440 has also associated a respective common mode voltage V_{CM}, which may be fixed or settable.

Accordingly, when the signal Φ₁ is asserted, the input terminals of the operational amplifier 3440 are set to the common mode voltage V_{CM}, which permits charging of the capacitances C₁ and C₂ via the voltages V₁ and V₂. Conversely, when the signal Φ₂ is asserted, the integration capacitances C_{I1} and C_{I2} are connected to the operational amplifier 3440 and the previously charged capacitances C₁ and C₂ discharge to the reference voltage V_{ref}/ground GND. Specifically, the charge applied to the capacitances C₁ and C₂ is different, e.g., when: the voltages V₁ and V₂ have the same value, e.g., V_{A}, but the capacitances C₁ and C₂ are different, which thus permits monitoring of the difference between the capacitances C₁ and C₂, or the capacitances C₁ and C₂ have the same value, but the voltages V₁ and V₂ are different, which thus permits monitoring of the difference between the voltages V₁ and V₂.

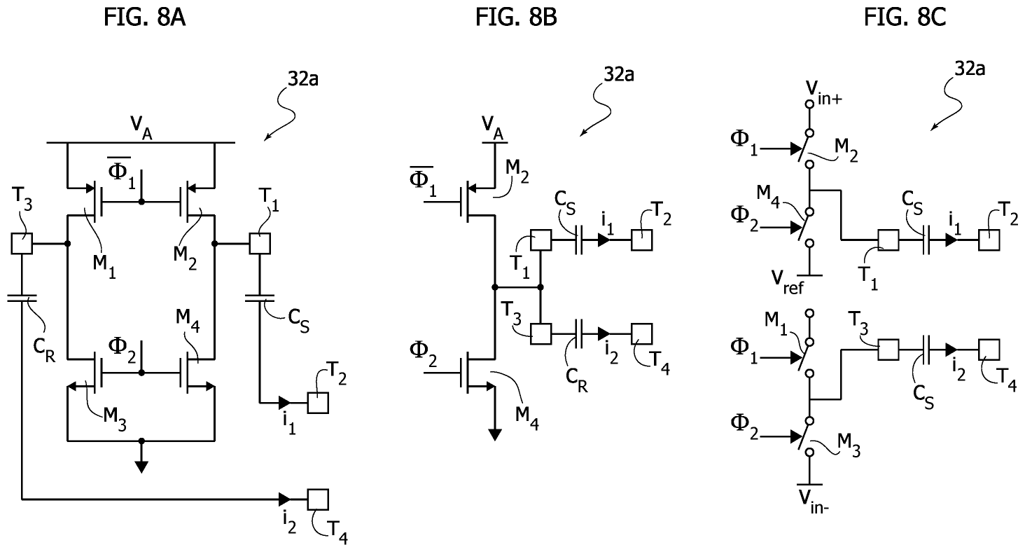

For example, FIGS. 8A, 8B and 8C show possible embodiments of the switching circuit 32a and the capacitances C₁ and C₂.

Specifically, in FIGS. 8A and 8B, the capacitance C₁ corresponds to a sense capacitance C_{S} and the capacitance C₂ corresponds to a reference capacitance C_{R}, i.e., the capacitance C_{S} has a variable capacitance value. Moreover, in this case, the voltages V₁ and V₂ are connected to a common voltage V_{A}, which may be provided via a terminal/pad/pin of the measurement system or via the voltage generator 42.

For example, the switching circuit 32a of FIG. 8A essentially corresponds to the switching circuit 32 shown in FIG. 2. Specifically, in the embodiment considered, the current path of a first electronic switch M₄, such as a transistor, such as an n-channel FET, such as an n-channel MOSFET, is connected (e.g., directly) between the terminal T₁ and the reference voltage V_{ref}/ground GND. Moreover, the current path of a second electronic switch M₂, such as a transistor, such as an p-channel Field-effect transistor (FET), such as an p-channel MOSFET, is connected (e.g., directly) between the terminal T₁ and the voltage V_{A}. Similarly, the current path of a third electronic switch M₃, such as a transistor, such as an n-channel FET, such as an n-channel MOSFET, is connected (e.g., directly) between the terminal T₃ and the reference voltage V_{ref}/ground GND. Moreover, the current path of a fourth electronic switch M₁, such as a transistor, such as an p-channel Field-effect transistor (FET), such as an p-channel MOSFET, is connected (e.g., directly) between the terminal T₃ and the voltage V_{A}.

For example, when the electronic switches M₁ and M₂ are implemented with p-channel FETs, the switches M₁ and M₂ are indeed closed when the signal Φ₁ is set to low. Thus, when the control circuit 36a is configured to assert the signal Φ₁ by setting signal Φ₁ to high, the inverted signal Φ̅₁ may be used to drive the gate terminal of the p-channel FETs M₁ and M₂ (see also FIG. 8A).

Accordingly, in the embodiment shown in FIG. 8A, the two half-bridges formed by the switches M₁/M₃ and M₂/M₄ indeed operate in parallel based on the same control signals. Accordingly, as shown in FIG. 8B, in various embodiments, the electronic switches M₁ and M₃ may be omitted, and the terminal T₃ of the reference capacitance C_{R} may be connected (e.g., directly) to the terminal T₁ of the sense capacitance C_{S}.

Conversely, in FIG. 8C, the capacitances C₁ and C₂ have the same value C_{S}. Moreover, the voltages V₁ is connected to a voltage Vᵢₙₜ₊ and the voltages V₂ is connected to a voltage Vᵢₙ₋.

Accordingly, also in this case two half-bridges may be used. For example, in the embodiment considered, the current path of a first electronic switch M₄, such as a transistor, such as an n-channel FET, such as an n-channel MOSFET, is connected (e.g., directly) between the terminal T₁ and the reference voltage V_{ref}/ground GND. Moreover, the current path of a second electronic switch M₂, such as a transistor, such as an p-channel Field-effect transistor (FET), such as an p-channel MOSFET, is connected (e.g., directly) between the terminal T₁ and the voltage Vᵢₙ₊. Similarly, the current path of a third electronic switch M₃, such as a transistor, such as an n-channel FET, such as an n-channel MOSFET, is connected (e.g., directly) between the terminal T₃ and the reference voltage V_{ref}/ground GND. Moreover, the current path of a fourth electronic switch M₁, such as a transistor, such as an p-channel Field-effect transistor (FET), such as an p-channel MOSFET, is connected (e.g., directly) between the terminal T₃ and the voltage Vᵢₙ₋.

Accordingly, the embodiments shown in FIGS. 8A and 8B may be used to monitor the difference ΔC between the capacitances C_{S} and C_{R}, while the embodiment shown in FIG. 8C may be used to monitor the amplitude of a differential voltage ΔVᵢₙ corresponding to the difference between the voltages Vᵢₙ₊ and Vᵢₙ₋.

For example, when using the measurement circuit 34a of FIG. 7 with the switching circuits 32a shown in FIGS. 8A and 8B, the following net charge will be injected into the integration capacitances C_{I1} and C_{I2} at each switching cycle T_{S}:

ΔQ=(C_{S}−C_{R})V_{A}=ΔC V_{A} (3)

Accordingly, assuming that the capacitances C_{I1} and C_{I2} have the same value C_{I} and when repeating a given number N of switching cycles T_{S}, the differential output voltage V_{O,AMP} of the operational amplifier 3440 during the intervals when the signal Φ₂ is asserted is given by:

$${V}_{O , AMP} = N \frac{Δ C}{{C}_{I}} {V}_{A} \qquad ( 4 )$$

Conversely, when using the measurement circuit 34a of FIG. 7 with the switching circuits 32a shown in FIG. 8C, the capacitances C_{S} are reset to the common mode voltage V_{CM} when the signal Φ₁ is asserted. Conversely, when the signal Φ₂ is asserted, a differential voltage ΔVᵢₙ (between Vᵢₙ₊ and Vᵢₙ₋) is applied to the capacitors C_{S}, thereby injecting the following net charge at each switching cycle T_{S}:

ΔQ=(Vᵢₙ₊−Vᵢₙ₋)C_{S}=ΔVᵢₙC_{S} (5)

Accordingly, assuming that the capacitances C_{I1} and C_{I2} have the same value C_{I} and when repeating a given number N of switching cycles T_{S}, the differential output voltage V_{O,AMP} of the operational amplifier 3440 during the intervals when the signal Φ₂ is asserted is given by:

$${V}_{O , AMP} = N \frac{{C}_{S}}{{C}_{I}} {Δ V}_{i n} \qquad ( 5 )$$

Specifically, when opening the electronic switches 3448 and 3450 once the signal Φ₂ is de-asserted, the differential voltage V_{O,AMP} is maintained and stored at the intermediate nodes between the integration capacitances (C_{I1} or C_{I2}) and the electronic switch (3448 or 3450). Accordingly, in the embodiment considered, the second terminal of the integration capacitance C_{I1}, i.e., the intermediate node between the capacitance C_{I1} and the electronic switch 3448, represents a first output terminal OUT+ of the integrator circuit, and the second terminal of the integration capacitance C_{I2}, i.e., the intermediate node between the capacitance C_{I2} and the electronic switch 3450, represents a second output terminal OUT− of the integrator circuit, wherein the output terminals OUT+ and OUT− provide a differential voltage V_{O}, e.g., corresponding to the previously indicated voltages V_{O,AMP}.

In various embodiments, the measurement circuit 34a may be configured to assert a signal S when the voltage V_{O} exceeds a reference threshold within a given monitoring interval, which comprises a given number N of switching/integration cycles T_{S}, thereby indicating that current difference Δi=i₁−i₂ exceeds a given threshold value, which in turn may indicate that the capacitance difference ΔC (e.g., FIG. 8A or 8B) or the differential voltage ΔVᵢₙ (e.g., FIG. 8C) exceeds a respective threshold. For example, the signal S may be provided to a terminal/pad/pin of the measurement system or, as shown in FIG. 6, to a digital and/or analog processing circuit 44 of the measurement system. For example, the processing circuit 44 may be a microprocessor programmed via software instructions.

Specifically, in various embodiments, the signal S is generated via a differential comparator with hysteresis 3446 configured to assert the signal S when the voltage V_{O} exceeds the hysteresis threshold of the comparator 3446.

In general, such a comparator with hysteresis 3446 comprises two input terminals for receiving a differential voltage ΔV_{CMP} and two output terminals form providing signals OUT and OUTN, wherein the comparator 3446 is configured to set the signal OUT to high and the signal OUTN to low in response to determining that the voltage at the negative input terminal exceeds the voltage at the positive input terminal plus a first hysteresis voltage V_{H1} of the comparator. Similarly, the comparator 3446 is configured to set the signal OUT to low and the signal OUTN to high in response to determining that the voltage at the negative input terminal falls below the voltage at the positive input terminal minus a second hysteresis voltage V_{H2}. In various embodiments, the first hysteresis voltage V_{H1} and the second hysteresis voltage V_{H2} have the same absolute value V_{H}.

Accordingly, in the embodiment considered, the signal S may correspond, e.g., to the signal OUT. Conversely, in the embodiment considered, the measurement circuit 34a comprises a first inverter 3460 configured to generate the signal S by inverting the signal OUTN. In this case, the measurement circuit 34a also comprises a second inverter 3462 configured to generate a signal SN by inverting the signal OUT. Specifically, these inverters 3460 and 3462 are useful in case the signals S and/or SN are used to drive other circuits, and may also be useful in order to balance the output terminals of the comparator with hysteresis 3446. In general, the inverters 3460 and 3462 may also be replaced with a more complex driver stage, e.g., comprising a cascade of inverters and/or other logic gates.

In the embodiment considered, the input terminals of the comparator 3446 are not connected directly to the nodes OUT+ and OUT−, but one of the input terminals of the comparator 3446, e.g., the negative input terminal, is connected (e.g., directly) via a first capacitance/capacitor C_{DEC1} to the node OUT+ and the other input terminal of the comparator 3446, e.g., the positive input terminal, is connected (e.g., directly) via a second capacitance/capacitor C_{DEC2} to the node OUT−. These capacitances C_{DEC1} and C_{DEC2} have the same capacitance value C_{DEC}.

On the one hand, these capacitances C_{DEC1} and C_{DEC2} represent decoupling capacitances between the integrator and the comparator, which thus transfer the variations of the voltages at the nodes OUT+ and OUT− to the input terminals of the comparator. However, in various embodiments, the offsets and most of the flicker noise of the operational amplifier 3440 and the comparator with hysteresis 3446 may be also stored to the capacitances C_{DEC1} and C_{DEC2} during a reset phase whereby these voltages are then cancelled during the subsequent sensing operation.

Specifically, in various embodiments, to order to start a new measurement cycle, an asynchronous reset is performed once the signal S is asserted, i.e., the signal S corresponds to a reset signal Reset1.

In general, the integrator 3440 may be reset by short-circuiting the integration capacitances C_{I1} and C_{I2}. For example, in FIG. 7, the integration capacitances C_{I1} and C_{I2} are reset, when the electronic switches 3448, 3450, 3452 and 3454 are closed contemporaneously. For example, in the embodiments considered, the electronic switches 3452 and 3454 are closed when the signal Φ₁ is asserted or the reset signal Reset1/S is asserted. For example, in the embodiment considered, the electronic switches 3452 and 3454 are driven via logic OR gates 3442 and 3444 configured to combine the signals Φ₁ and Reset1.

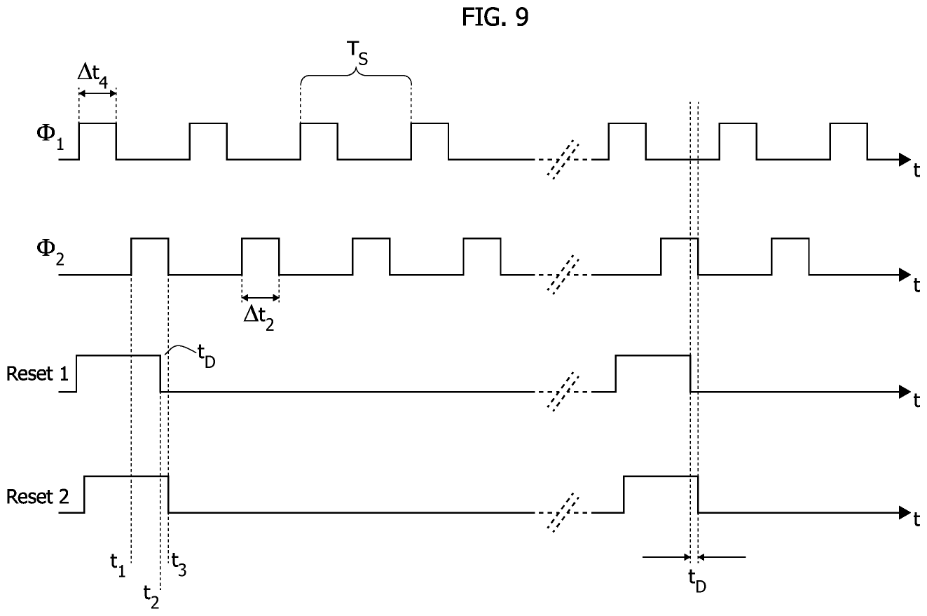

Accordingly, as shown in FIG. 9, once the signal S is asserted during a given discharge phase Δt₄ (when the signal Φ₁ is asserted), the reset signal Reset1 is also asserted. Accordingly, at the next charge phase Δt₂ (when the signal Φ₂ is asserted), the integration capacitances C_{I1} and C_{I2} are short-circuited, whereby the integrator is reset.

In various embodiments, the comparator with hysteresis 3446 is also reset during the reset phase. For example, in various embodiments, the comparator 3446 is reset by closing an electronic switch 3464 configured to short-circuit the output terminal OUTN and the negative input terminal of the comparator 3446 and an electronic switch 3466 configured to short-circuit the output terminal OUT and the positive input terminal of the comparator 3446.

In various embodiments, the electronic switches 3464 and 3466 are closed when the signal Reset1 is asserted. Conversely, in the embodiment shown in FIG. 7, the electronic switches 3464 and 3466 are closed when a reset signal Reset2 is asserted, wherein the reset signal Reset2 corresponds to the reset signal Reset1 with a given delay t_{D}. For example, the reset signal Reset2 may be generated via a delay circuit 3456, such as a delay line, receiving the reset signal Reset1 as input. For example, in FIG. 7 is shown a first delay circuit 3456 configured to generate the drive signal of the electronic switch 3464 by delaying the signal Reset1, and a second delay circuit 3458 configured to generate the drive signal of the electronic switch 3466 by delaying the signal Reset1.

Accordingly, as shown in FIG. 9, when the signal S/Reset1 is asserted and the control circuit 32a asserts at an instant t₁ the signal Φ₂, the capacitances C_{I1} and C_{I2} are discharged and the comparator 3446 is reset. Accordingly at a following instant t₂ the signal S goes to low. However, this falling edge is just propagated to the reset signal Reset2 after a delay t_{D}. Accordingly, for the time t_{D}, the reset signal Reset1 is de-asserted (and similarly the signal Φ₁), while the signal Φ₂ and the reset signal Reset2 are still asserted. Accordingly, in this condition the electronic switches 3452 and 3454 are opened and:
the electronic switches 3448 connect the capacitance Cₙ between the inverting/negative input terminal of the operational amplifier 3440 and the positive output terminal of the operational amplifier 3440;
the electronic switches 3450 connect the capacitance C_{I2} between the non-inverting/positive input terminal of the operational amplifier 3440 and the negative output terminal of the operational amplifier 3440;
the electronic switch 3464 connects the negative input terminal of the comparator 3446 to the terminal OUTN; and
the electronic switch 3466 connects the positive input terminal of the comparator 3446 to the terminal OUT.

Accordingly, in the embodiment considered, the offsets and most of the flicker noise of the operational amplifier 3440 and the comparator with hysteresis 3446 are stored to the capacitances C_{DEC1} and C_{DEC2} during the interval between the instants t₁ and t₂. Conversely, when using the optional delay t_{D}, the charge-injection and clock-feedthrough of the switches 3452 and 3454 may also be stored to the capacitances C_{DEC1} and C_{DEC2}.

In this respect, it has been observed that the remaining error may in this way be reduced to the mismatch of the charge-injection and clock-feedthrough of the switches 3464 and 3466 driven by the reset signal Reset2, i.e., Vₑᵣᵣₒᵣ=ΔQ_{SW}/C_{DEC}, wherein the voltage Vₑᵣᵣₒᵣ is usually in the micro-Volt range, and usually can be neglected or anyway absorbed by the comparator hysteresis.

In this respect, it has been observed that a smaller threshold voltage V_{H1} permits a faster detection, e.g., of the sample passing over the electrodes 100 and 102 forming the capacitance C_{S}. However, such a smaller threshold voltage V_{H1} may imply thermal noise and the charge injection/clock feedthrough mismatch of the switches 3464 and 3466 driven by the signal Reset2 on the measurement.

Additionally, or alternatively, to the asynchronous reset triggered by the signal S, the reset of the measurement circuit 34a may also be managed based on a timeout, which is used to trigger similar reset phases of the integrator and the comparator. In fact, in line with the previous description, in various embodiments, the measurement system comprises a reset circuit configured to execute, in response to a reset request signal indicating a reset request, such as a rising edge of the signal S, a signal indicating that a given maximum number N of switching cycles have been executed, etc., the following steps in sequence:
in an optional first phase, e.g., between the rising edge of the Reset1 signal and instant t₁, close the electronic switches 3452, 3454, 3464 and 3466;
in a (immediately following) second phase, e.g., between the instants t₁ and t₂, close the electronic switches 3448, 3450, and keep the electronic switches 3452, 3454, 3464 and 3466 closed;
in an optional (immediately following) third phase, e.g., between the instants t₂ and t₃, open the electronic switches 3452 and 3454 and keep the electronic switches 3448, 3450, 3464 and 3466 closed.

In various embodiments, in order to absorb the differential charge injection of the feedback switches 3448 and 3450 driven by Φ₂ in presence of a differential signal at the output terminals of the operational amplifier 3440, these switches may be equipped with dummy switches and/or capacitor C_{X} is added.

For example, in the embodiment shown in FIG. 7, a first capacitor C_{X1} is connected (e.g., directly) between the terminal OUT+ and a reference voltage, such as ground GND, and a second capacitor C_{X2} is connected (e.g., directly) between the terminal OUT− and the reference voltage, such as ground GND. The capacitors C_{X1} and C_{X2} have the same capacitance value.

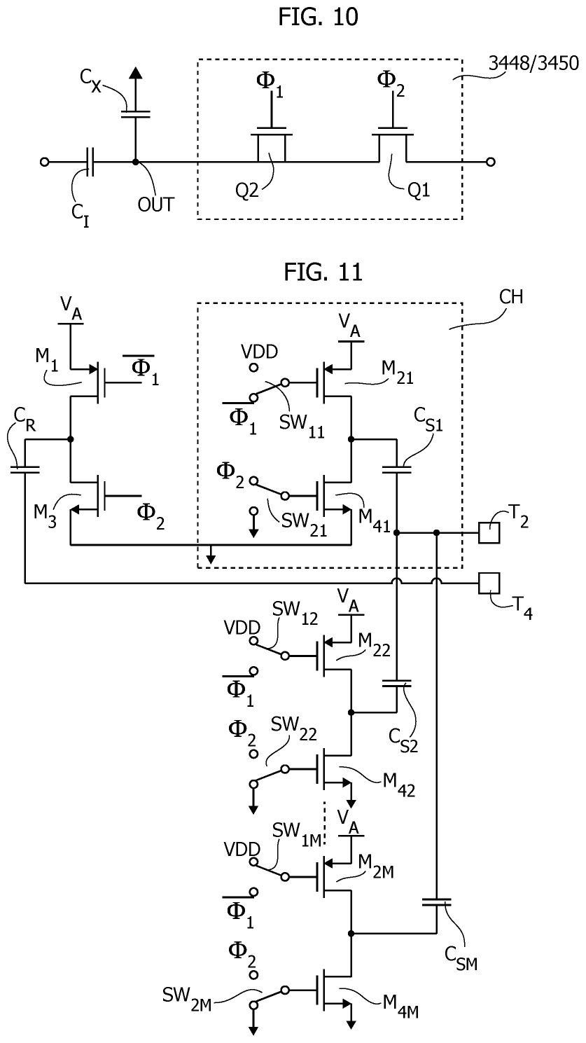

Conversely, FIG. 10 shows a possible implementation of each of the switches 3448 and 3450.

Specifically, in the embodiment considered, a first terminal of a respective integration capacitance C_{I1} or C_{I2}, indicated generically as C_{I} in FIG. 10, is connected to a respective input terminal of the operational amplifier 3440 and the electronic switch 3448/3450 is connected between the second terminal of the respective integration capacitance C_{I} and a respective output node of the operational amplifier 3440, wherein the intermediate node between the integration capacitance C₁ and the electronic switch 3448/3450 corresponds to an output node OUT+ or OUT− of the integrator, generically indicated as node OUT. As mentioned before, optionally a capacitor C_{X1} or C_{X2}, generically indicated as capacitor C_{X} in FIG. 10, may be connected between the output node OUT and a reference voltage, e.g., ground GND.

Specifically, in the embodiment considered, each electronic switch 3448/3450 is implemented with a series connection of two FETs Q1 and Q2, such as n-channel FETs. Specifically, the first FET Q1 is driven via the signal Φ₂. Conversely, the second FET Q2 is a dummy switch, wherein the source and drain terminals of the FET Q2 are short-circuited. Moreover, the gate terminal of the FET Q2 is driven via a signal being asserted when the signal Φ₂ is de-asserted, such as the inverted version of the signal Φ₂ or preferably the signal Φ₁. Preferably, the FET Q1 has a given size ratio W₁/L₁ (channel width/length), and the FET has a ratio W₂/L₂ corresponding to 0.5 W₁/L₁. Generally, such dummy switches Q2 for reducing the charge injection are well-known.

Accordingly the solutions described in the foregoing have the advantage that the voltage V_{O,AMP} and similarly V_{O} is not sensitive to process parameters, such as the MOS voltage threshold of the current mirrors of the prior-art solution. Moreover, the voltages V₁ and V₂ may be external or internal voltages. For example, the voltage V_{A} may correspond to a supply voltage VDD of the integrated circuit 40 or a reference voltage provided by the voltage reference 42. Specifically, when using an internal voltage reference 42 configured to generate the voltage V_{A}, the threshold value V_{H1} (and optionally V_{H2}) may also be proportional the voltage V_{A}, thereby permitting a tracking of variation of the voltage V_{A} variations. Conversely, a higher sensitivity can be achieved when using the (greater) supply voltage VDD.

For example, in various embodiment, the integration capacitances C_{I1} and C_{I2} have a capacitance value of 0.1 pF, the period of a switching cycle T_{S} is 1 μs, the voltage V_{A} has a value of 2.5 V, and the comparison threshold V_{H1} (and optionally V_{H2}) is 5 mV. For example, assuming a capacitance difference ΔC of 10 aF, the voltage V_{O} reaches the comparison threshold V_{H1} after N=20 switching cycles T_{S}. Thus, in this example, the measurement system is able to detect the presence or absence of a sample, such as a sample with small radius crossing the plates of capacitor C_{S}, producing a change ΔC of 10 aF in approximately 20 μs. Conversely, assuming a capacitance difference ΔC of 40 aF, the voltage V_{O} reaches the comparison threshold V_{H1} after N=5 switching cycles T_{S}, i.e., the measurement system is able to detect the presence or absence of a sample producing a change ΔC of 40 aF in approximately 5 μs.

In general, the measurement circuit 34a disclosed in the foregoing may also be used with a plurality of capacitive sensors. For example, such capacitive sensors may form part of a capacitive touch sensor, such as a touch screen.

For example, FIG. 11 shows an embodiment, wherein a single reference capacitance C_{R} and a given number M of sense capacitances C_{S1}, C_{S2}, . . . , C_{SM} are used.

Specifically, similar to FIG. 8A, a first terminal of the reference capacitance C_{R} is again connected (e.g., directly) to the node T₄ connected to the measurement circuit 34a and the second terminal of the reference capacitance C_{R} is again connected (e.g., directly) to the intermediate node of the half-bridge formed by the electronic switches M₁ and M₃. Conversely, a first terminal of each sense capacitance C_{S1}, C_{S2}, . . . , C_{SM} is connected (e.g., directly) to the node T₂ connected to the measurement circuit 34a and the second terminal of each sense capacitance C_{S1}, C_{S2}, . . . , C_{SM} is connected (e.g., directly) to the intermediate node of a respective half-bridge formed by a high-side switch and a low-side switch electronic switches, i.e., half-bridges formed by two electronic switches M₂₁ and M₄₁, two electronic switches M₂₂ and M₄₂, etc. Specifically, in the embodiment considered, the various half-bridges are configured to connect the respective intermediate node via a respective high-side switch to the voltage V_{A} and via the respective low-side switch to the reference voltage V_{ref}/ground GND. Accordingly, in the embodiment considered, the measurement system comprises a single half-bridge for the reference capacitance C_{R} and a respective half-bridge for each of the M sense capacitances C_{S1}, C_{S2}, . . . , C_{SM}.

Specifically, in order to select a given channel CH, the control terminal of the electronic switches M₂₁, M₄₁, . . . , M_{2M}, M_{4M} are selectively connected to the control signals Φ₁ and Φ₂. For example, assuming that the high-side electronic switches M₂₁, . . . , M_{2M} are p-channel FETs and the low-side electronic switches M₄₁, . . . , M_{4M} are n-channel FETs, a given channel CH may be:
enabled by connecting the gate terminal of the respective high-side electronic switch M₂₁, . . . , M_{2M} to the signal Φ̅₁ and the gate terminal of the respective low-side electronic switch M₄₁, . . . , M_{4M} to the signal Φ₂; and
disabled by connecting the gate terminal of the respective high-side electronic switch M₂₁, . . . , M_{2M} to a high logic level, such as the supply voltage VDD, and the gate terminal of the respective low-side electronic switch M₄₁, . . . , M_{4M} to a low logic level, such as ground GND.

For example, for this purpose, each high-side electronic switch M₂₁, . . . , M_{2M} has an associated respective electronic switch SW₁₁, SW₁₂, . . . , SW_{1M} configured to connect the respective gate terminal to the high logic level or the signal Φ̅₁, and each low-side electronic switch M₄₁, . . . , M_{4M} has an associated respective electronic switch SW₂₁, SW₂₂, . . . , SW_{2M} configured to connect the respective gate terminal to the low logic level or the signal Φ₂. For example, the control signal for the electronic switches SW₁₁, SW₁₂, . . . , SW_{1M} and SW₂₁, SW₂₂, . . . , SW_{2M} may be generated by the control circuit 36a or the processing circuit 44 (not shown in FIG. 11). Accordingly, in the embodiment considered, one of the sense capacitances is usually connected to the terminal T₂.

While this embodiment permits use of a single reference capacitance C_{R}, a large loading is applied to the node T₂ (e.g., the negative input terminal of the operational amplifier 3440), and a strong capacitive asymmetry is generated between the nodes T₂ and T₄ (the input terminals of the amplifier 3440).

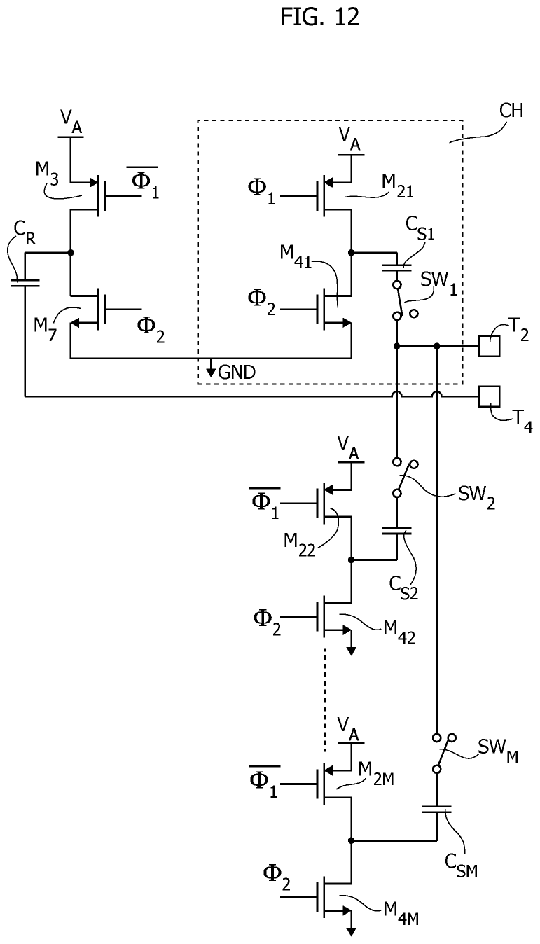

FIG. 12 shows thus a slightly different embodiment.

In the embodiment considered, similar to FIG. 11, a first terminal of the reference capacitance C_{R} is again connected (e.g., directly) to the node T₄ and the second terminal of the reference capacitance C_{R} is again connected (e.g., directly) to the intermediate node of the half-bridge formed by the electronic switches M₁ and M₃. However, this time a first terminal of each sense capacitance C_{S1}, C_{S2}, . . . , C_{SM} is connected (e.g., directly) to the intermediate node of a respective half-bridge formed by two electronic switches, i.e., half-bridges formed by two electronic switches M₂₁ and M₄₁, two electronic switches M₂₂ and M₄₂, etc., and the second terminal of each sense capacitance C_{S1}, C_{S2}, . . . , C_{SM} is connected (e.g., directly) via a respective electronic switch SW₁, SW₂, . . . , SW_{M} to the node T₂.

Specifically, in the embodiment considered, the various half-bridges are configured to connect the respective intermediate node to the voltage V_{A} when the signal Φ̅₁ is asserted and to the reference voltage V_{ref}/ground GND when the signal Φ₂ is asserted, i.e., the electronic switches SW₁₁, SW₂₁, . . . , SW_{1M}, SW_{2M} are omitted. Conversely, each of the electronic switches SW₁, SW₂, . . . , SW_{M} may be driven via a respective control signal in order to connect the respective sense capacitance C_{S1}, C_{S2}, . . . , C_{SM} to the respective half-bridge. Thus, by closing one of the electronic switches SW₁, SW₂, . . . , SW_{M} a respective channel CH may be enabled. For example, the control signal for the electronic switches SW₁, SW₂, . . . , SW_{M} may be generated by the control circuit 36a or the processing circuit 44 (not shown in FIG. 12). Accordingly, in the embodiment considered, one of the sense capacitances is usually connected to the terminal T₂.

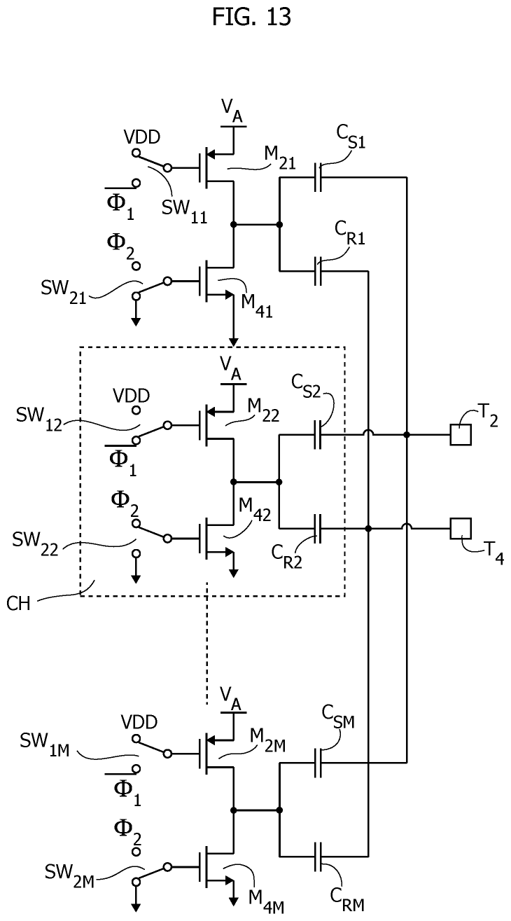

FIG. 13 shows an embodiment based on a combination of the embodiments of FIGS. 8B and 11. Specifically, in this embodiment M reference capacitances C_{R1}, C_{R2}, . . . , C_{RM} and M sense capacitances C_{S1}, C_{S2}, . . . , C_{SM} are used.

Specifically, similar to FIG. 8B, in this case, a reference capacitance C_{R} and a sense capacitance C_{S} are connected to a respective half-bridge. Specifically, a first terminal of each sense capacitance C_{S1}, C_{S2}, . . . , C_{SM} is connected (e.g., directly) to the node T₂ and the second terminal of each sense capacitance C_{S1}, C_{S2}, . . . , C_{SM} is connected (e.g., directly) to the intermediate node of the respective half-bridge formed by two electronic switches, i.e., half-bridges formed by two electronic switches M₂₁ and M₄₁, two electronic switches M₂₂ and M₄₂, etc. Moreover, a first terminal of each reference capacitance C_{R1}, C_{R2}, . . . , C_{RM} is connected (e.g., directly) to the node T₄ and the second terminal of each reference capacitance C_{R1}, C_{R2}, . . . , C_{RM} is connected (e.g., directly) to the intermediate node of the respective half-bridge. Accordingly, in the embodiment considered, the measurement system comprises M half-bridges, one for each channel CH comprising a respective reference capacitance C_{R} and a respective sense capacitance C_{S}.

In the embodiment considered, similar to FIG. 11, each high-side electronic switch M₂₁, . . . , M_{2M} has an associated respective electronic switch SW₁₁, SW₁₂, . . . , SW_{1M} configured to connect the respective gate terminal to the high logic level or the signal (P, and each low-side electronic switch M₄₁, . . . , M_{4M} has an associated respective electronic switch SW₂₁, SW₂₂, . . . , SW_{2M} configured to connect the respective gate terminal to the low logic level or the signal Φ₂. For example, the control signal for the electronic switches SW₁₁, SW₁₂, . . . , SW_{1M} and SW₂₁, SW₂₂, . . . , SW_{2M} may be generated by the control circuit 36a or the processing circuit 44 (not shown in FIG. 13).

Thus, compared to FIG. 11, the measurement system here has a rather symmetric capacitive load. However, also in this case, the measurement system has a large loading on the input terminals of the operational amplifier 3440.

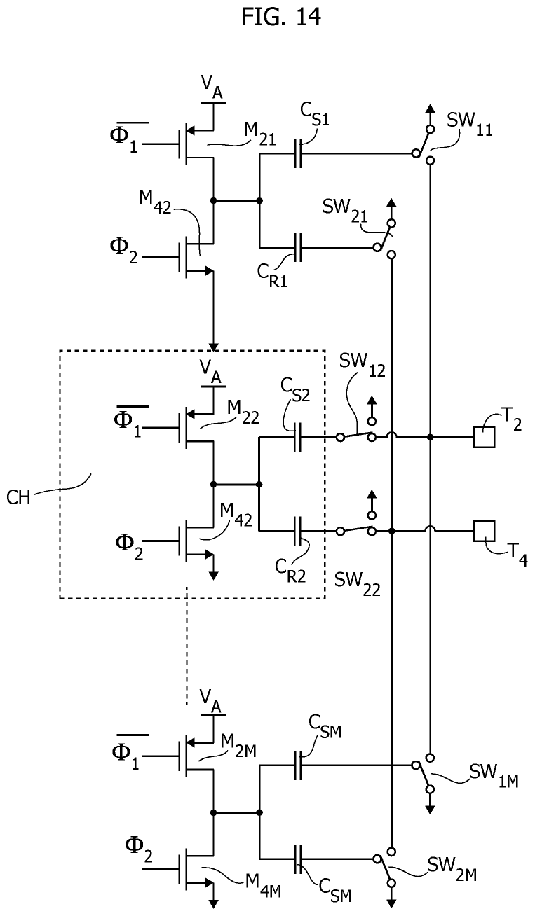

FIG. 14 shows thus a slightly different embodiment.

Specifically, a reference capacitance C_{R} and a sense capacitance C_{S} are again connected to a respective half-bridge. Specifically, a first terminal of each sense capacitance C_{S1}, C_{S2}, . . . , C_{SM} is connected (e.g., directly) to the intermediate node of the respective half-bridge formed by two electronic switches, i.e., half-bridges formed by two electronic switches M₂₁ and M₄₁, two electronic switches M₂₂ and M₄₂, etc., and the second terminal of each sense capacitance C_{S1}, C_{S2}, . . . , C_{SM} is connected (e.g., directly) via a respective electronic switch SW₁₁, SW₁₂, . . . , SW_{1M} to the node T₂. Moreover, a first terminal of each reference capacitance C_{R1}, C_{R2}, . . . , C_{RM} is connected (e.g., directly) to the intermediate node of the respective half-bridge and the second terminal of each reference capacitance C_{R1}, C_{R2}, . . . , C_{RM} is connected (e.g., directly) via a respective electronic switch SW₂₁, SW₂₂, . . . , SW_{2M} to the node T₂.

Thus, the electronic switches SW₁₁, SW₁₂, . . . , SW_{1M} and SW₂₁, SW₂₂, . . . , SW_{2M} may be driven via respective control signals in order to connect a single sense capacitance C_{S1}, C_{S2}, . . . , C_{SM} and a single reference capacitance C_{R1}, C_{R2}, . . . , C_{RM} to the respective half-bridge. For example, the control signals may be generated by the control circuit 36a or the processing circuit 44 (not shown in FIG. 14).

In general, the embodiments shown in FIGS. 11 and 12, and similarly FIGS. 13 and 14, may also be combined, i.e., the measurement system may comprise electronic switches for selectively connecting the control terminals of the electronic switches M₂₁, M₄₁, . . . , M_{2M}, M_{4M} to the signals Φ̅₁ and Φ₂ (as shown in FIGS. 11 and 13) and electronic switches for selectively connecting the sense capacitances to the node T₂ (as shown in FIGS. 12 and 14). Similarly, in case of a plurality of reference capacitances, the measurement system may also comprise electronic switches for selectively connecting the reference capacitances to the node T₄ (as shown in FIG. 14).

Accordingly, the measurement system 34a disclosed herein may be used to monitor a different charge injected into two capacitances C₁ and C₂, which in turn may be indicative of a different capacitance value of the two capacitances C₁ and C₂ or a different voltage V₁ and V₂ used to charge the capacitances C₁ and C₂.

For example, in the context of a capacitive sensor, the measurement system may be used to detect the presence of a sample material across an integrated capacitor in a very accurate way. In this case, the sensitivity of the measurement system is mainly determined by the mismatch between the reference and the sensing capacitors.

Compared to the prior art solutions, the detection is very fast. In this respect, the asynchronous detection based on an asynchronous reset via the signal S permits further increase of the speed of the system.

Finally, several simple and low-cost multiplexing solutions available.

Of course, without prejudice to the principle of this disclosure, the details of construction and the embodiments may vary widely with respect to what has been described and illustrated herein purely by way of example, without thereby departing from the scope of the present invention, as defined by the ensuing claims.

1. A measurement system, comprising:
a first capacitance and a second capacitance;
a switching circuit configured to receive a first control signal and a second control signal and:
in response to said first control signal being asserted, connect a first terminal of said first capacitance to a first voltage and a first terminal of said second capacitance to a second voltage; and
in response to said second control signal being asserted, connect said first terminal of said first capacitance and said first terminal of said second capacitance to a reference voltage;
a control circuit configured to generate said first control signal and said second control signal according to switching cycles, wherein said control circuit is configured to repeat, during each switching cycle:
for a first interval, de-assert said first control signal and said second control signal,
for a second interval, de-assert said first control signal and assert said second control signal,
for a third interval, de-assert said first control signal and said second control signal, and
for a fourth interval, assert said first control signal and de-assert said second control signal;
a measurement circuit comprising:
a differential integrator comprising:
a differential operational amplifier having an inverting input connected to a second terminal of said first capacitance and a non-inverting input connected to a second terminal of said second capacitance;
a first integration capacitance having a first terminal connected to said inverting input of said differential operational amplifier and a second terminal connected via a first electronic switch to a positive output terminal of said differential operational amplifier;
a first output node of said differential integrator connected to said second terminal of said first integration capacitance;
a second integration capacitance having a first terminal connected to said non-inverting input of said differential operational amplifier and a second terminal connected via a second electronic switch to a negative output terminal of said differential operational amplifier;
a second output node of said differential integrator connected to said second terminal of said second integration capacitance;
a third electronic switch connected between said inverting input of said differential operational amplifier and said positive output terminal of said differential operational amplifier; and
a fourth electronic switch connected between said non-inverting input of said differential operational amplifier and said negative output terminal of said differential operational amplifier; and
a comparator with hysteresis configured, in response to a voltage applied to a negative input terminal of said comparator exceeding a voltage applied to a positive input terminal of said comparator plus a hysteresis threshold, to set a first output terminal of said comparator to high and a second output terminal of said comparator to low, wherein said comparator comprises:
a fifth electronic switch connected between said negative input terminal of said comparator and said second output terminal of said comparator;
a sixth electronic switch connected between said positive input terminal of said comparator and said first output terminal of said comparator;
a first decoupling capacitance connected between the negative input terminal of said comparator and said first output node of said differential integrator; and
a second decoupling capacitance connected between the positive input terminal of said comparator and said second output node of said differential integrator;
the control circuit further configured to:
during a normal operation phase:
close said first electronic switch and said second electronic switch by asserting said second control signal, and open said first electronic switch and said second electronic switch by de-asserting said second control signal;
close said third electronic switch and said fourth electronic switch by asserting said first control signal, and open said third electronic switch and said fourth electronic switch by de-asserting said first control signal;
open said fifth electronic switch and said sixth electronic switch; and
monitor a reset request signal indicating a reset request and start a reset phase in response to determining that said reset request signal indicates a reset request; and
during said reset phase:
for a first reset interval, close said first electronic switch, second electronic switch, third electronic switch, fourth electronic switch, fifth electronic switch and sixth electronic switch; and
for a second reset interval, open said third electronic switch and said fourth electronic switch and maintain said first electronic switch, second electronic switch, fifth electronic switch, and sixth electronic switch as being closed, and then start said normal operation phase again.

2. The measurement system according to claim 1,
wherein said differential integrator is configured to receive a first reset signal, wherein said third electronic switch and said fourth electronic switch are configured to be closed in response to said first control signal being asserted or said first reset signal being asserted;
wherein said comparator is configured to receive a second reset signal, wherein said fifth electronic switch and said sixth electronic switch are configured to be closed in response to said second reset signal being asserted; and
wherein control circuitry is configured, while said second control signal is asserted:
for said first reset interval, to assert said first reset signal and said second reset signal, and
for said second reset interval, to de-assert said first reset signal and assert said second reset signal.

3. The measurement system according to claim 2, further comprising a delay circuit configured to generate said second reset signal by delaying said first reset signal.

4. The measurement system according to claim 1, wherein said measurement circuit is configured to assert said reset request signal after a given maximum number of said switching cycles.

5. The measurement system according to claim 1, wherein said measurement circuit is configured to assert said reset request signal in response to determining that said first output terminal of said comparator is set to high; or wherein said measurement circuit is configured to assert said reset request signal in response to determining that said second output terminal of said comparator is set to low.

6. The measurement system according to claim 1, further comprising: a processing circuit configured to monitor a signal at said first output terminal of said comparator; or a processing circuit configured to monitor a signal at said second output terminal of said comparator.

7. The measurement system according to claim 1, wherein said first capacitance corresponds to a sense capacitance and said second capacitance corresponds to a reference capacitance, wherein said first voltage and said second voltage have a common voltage, and wherein the voltage between the first output node and second output node of said differential integrator is indicative of a difference between capacitance values of said sense capacitance and said reference capacitance.

8. The measurement system according to claim 7, further comprising a voltage generator configured to generate said common voltage.

9. The measurement system according to claim 8,
further comprising a plurality of sense capacitances, wherein said switching circuit comprises for each sense capacitance a respective half-bridge, wherein each half-bridge comprises a high-side electronic switch connected between said common voltage and a first terminal of the respective sense capacitance, and a low-side electronic switch connected between said reference voltage and the first terminal of the respective sense capacitance; and
wherein said switching circuit comprises:
for each sense capacitance a respective electronic switch configured to selectively connect a second terminal of the respective sense capacitance to said inverting input of said differential operational amplifier; or
for each sense capacitance a respective electronic switch configured to selectively connect a control terminal of the respective high-side electronic switch to said first control signal or a voltage arranged to maintain opened the respective high-side electronic switch and a respective electronic switch configured to selectively connect a control terminal of the respective low-side electronic switch to said second control signal or a voltage arranged to maintain opened the respective low-side electronic switch.

10. The measurement system according to claim 9, further comprising a single reference capacitance, wherein said switching circuit comprises a further half-bridge comprising a further high-side electronic switch connected between said common voltage and a first terminal of the reference capacitance, and a further low-side electronic switch connected between said reference voltage and the first terminal of said reference capacitance.

11. The measurement system according to claim 9, further comprising for each sense capacitance a respective reference capacitance, wherein a first terminal of each reference capacitance is connected to the first terminal of the respective sense capacitance.

12. The measurement system according to claim 1, wherein said first capacitance and said second capacitance have a same capacitance value, wherein the voltage between the first output node and the second output node of said differential integrator is indicative of a difference between said first voltage and said second voltage.

13. An integrated circuit comprising a measurement system according to claim 1.

14. A measurement system, comprising:
first and second capacitances;
a switching circuit having a first terminal coupled to a reference voltage, a second terminal coupled to a first voltage greater than the reference voltage, and a third terminal coupled to a second voltage greater than the reference voltage;
the switching circuit receiving first and second control signals, and configured to couple first terminals of the first and second capacitances to different ones of the reference, first, and second voltages depending on the first and second control signals, such that:
in response to the first control signal being asserted while the second control signal is deasserted, couple the first terminal of the first capacitance to the first voltage and couple the first terminal of the second capacitance to the second voltage;
in response to the first control signal being deasserted while the second control signal is asserted, couple the first terminals of the first and second capacitances to the reference voltage; and
in response to the first and second control signals being deasserted, decouple the first terminals of the first and second capacitances from the first, second, and reference voltages; and
a measurement circuit configured to monitor resulting currents flowing through the first and second capacitances, with these currents being indicative of capacitance values of the first and second capacitances.

15. The measurement system of claim 14, wherein the reference voltage is ground.

16. The measurement system of claim 14, wherein the first and second voltages are equal to a voltage generated by a voltage generator.

17. The measurement system of claim 14, wherein the measurement circuit comprises:
a differential operational amplifier having an inverting input connected to a second terminal of the first capacitance and a non-inverting input connected to a second terminal of the second capacitance;
a differential comparator having an inverting input coupled to the inverting input of the differential operational amplifier through a first decoupling capacitor connected in series with a first integration capacitor, a non-inverting input coupled to the non-inverting input of the differential operational amplifier through a second decoupling capacitor connected in series with a second integration capacitor;
a first switch connected between a first tap and a non-inverting output of the differential operational amplifier, the first tap being between the first decoupling capacitor and first integration capacitor, the first switch controlled based upon the second control signal;
a second switch connected between a second tap and an inverting output of the differential operational amplifier, the second tap being between the second decoupling capacitor and second integration capacitor, the second switch controlled based upon the second control signal; and
a processing circuit having a first input coupled to the first output of the differential comparator, a second input coupled to the second output of the differential comparator, and an output, the processing circuit configured to determine capacitance values of the first and second capacitances.

18. The measurement system of claim 17, further comprising:
a first reset switch connected between the inverting input of the comparator and the first output of the comparator, the first reset switch controlled based upon the first output of the differential comparator through a first delay circuit; and
a second reset switch connected between the non-inverting input of the comparator and the second output of the comparator, the second reset switch controlled based upon the second output of the differential comparator through a second delay circuit.

19. The measurement system of claim 18, further comprising:
a third switch connected between the inverting input and non-inverting output of the differential operational amplifier, the third switch being controlled as a function of a logical OR operation performed between the first control signal and the first output of the differential comparator; and
a fourth switch connected between the non-inverting input and inverting output of the differential operational amplifier, the fourth switch being controlled as a function of a logical OR operation performed between the first control signal and the first output of the differential comparator.

20. A measurement system, comprising:
a first capacitance and a second capacitance;
a switching circuit configured to receive a first control signal and a second control signal and:
in response to assertion of said first control signal: connect a first terminal of said first capacitance to a first voltage, and connect a first terminal of said second capacitance to a second voltage; and
in response to assertion of said second control signal: connect said first terminal of said first capacitance and said first terminal of said second capacitance to a reference voltage; and
a measurement circuit comprising a differential integrator, the differential integrator comprising:
a differential operational amplifier having an inverting input connected to a second terminal of said first capacitance and a non-inverting input connected to a second terminal of said second capacitance;
a first integration capacitance having a first terminal connected to said inverting input of said differential operational amplifier and a second terminal connected via a first electronic switch to a positive output terminal of said differential operational amplifier, wherein said second terminal of said first integration capacitance represents a first output node of said differential integrator;
a second integration capacitance having a first terminal connected to said non-inverting input of said differential operational amplifier and a second terminal connected via a second electronic switch to a negative output terminal of said differential operational amplifier, wherein said second terminal of said second integration capacitance represents a second output node of said differential integrator;
a third electronic switch connected between said inverting input of said differential operational amplifier and said positive output terminal of said operational amplifier, and
a fourth electronic switch connected between said non-inverting input of said differential operational amplifier and said negative output terminal of said operational amplifier;
a comparator with hysteresis configured, in response to a voltage applied to a negative input terminal of said comparator exceeding a voltage applied to a positive input terminal of said comparator plus a hysteresis threshold, to set a first output terminal of said comparator to high and a second output terminal of said comparator to low, wherein said comparator comprises:
a fifth electronic switch connected between said negative input of said comparator and said second output terminal of said comparator; and
a sixth electronic switch connected between said positive input of said comparator with hysteresis and said first output terminal of said comparator; and
a first decoupling capacitance connected between the negative input of said comparator and said first output node of said differential integrator, and a second decoupling capacitance connected between the positive input of said comparator and said second output node of said differential integrator.

21. The measurement system according to claim 20,
wherein said differential integrator is configured to receive a first reset signal, wherein said third electronic switch and said fourth electronic switch are configured to be closed in response to assertion of said first control signal or assertion of said first reset signal; and
wherein said comparator is configured to receive a second reset signal, wherein said fifth electronic switch and said sixth electronic switch are configured to be closed in response to assertion of said second reset signal.

22. The measurement system according to claim 21, further comprising a delay circuit configured to generate said second reset signal by delaying said first reset signal.

23. The measurement system according to claim 20, wherein said first capacitance corresponds to a sense capacitance and said second capacitance corresponds to a reference capacitance, wherein said first voltage and said second voltage have a common voltage, and wherein the voltage between the first output node and second output node of said differential integrator is indicative of a difference between capacitance values of said sense capacitance and said reference capacitance.

24. The measurement system according to claim 23, further comprising a voltage generator configured to generate said common voltage.

25. The measurement system according to claim 24,
further comprising a plurality of sense capacitances, wherein said switching circuit comprises for each sense capacitance a respective half-bridge, wherein each half-bridge comprises a high-side electronic switch connected between said common voltage and a first terminal of the respective sense capacitance, and a low-side electronic switch connected between said reference voltage and the first terminal of the respective sense capacitance, and
wherein said switching circuit comprises at least one of:
for each sense capacitance a respective electronic switch configured to selectively connect a second terminal of the respective sense capacitance to said inverting input of said differential operational amplifier; and
for each sense capacitance a respective electronic switch configured to selectively connect a control terminal of the respective high-side electronic switch to said first control signal or a voltage arranged to maintain opened the respective high-side electronic switch and a respective electronic switch configured to selectively connect a control terminal of the respective low-side electronic switch to said second control signal or a voltage arranged to maintain opened the respective low-side electronic switch.

26. The measurement system according to claim 25, further comprising a single reference capacitance, wherein said switching circuit comprises a further half-bridge comprising a further high-side electronic switch connected between said common voltage and a first terminal of the reference capacitance, and a further low-side electronic switch connected between said reference voltage and the first terminal of said reference capacitance.

27. The measurement system according to claim 25, further comprising for each sense capacitance a respective reference capacitance, wherein a first terminal of each reference capacitance is connected to the first terminal of the respective sense capacitance.

28. The measurement system according to claim 20, wherein said first capacitance and said second capacitance have a same capacitance value, wherein the voltage between the first output node and the second output node of said differential integrator is indicative of a difference between said first voltage and said second voltage.

29. A method of operating the measurement system according to claim 20, the method comprising:
during a normal operation phase:
closing said first electronic switch and said second electronic switch in response to determining that said second control signal is asserted, and opening said first electronic switch and said second electronic switch in response to determining that said second control signal is de-asserted,
closing said third electronic switch and said fourth electronic switch in response to determining that said first control signal is asserted, and opening said third electronic switch and said fourth electronic switch in response to determining that said first control signal is de-asserted,
opening said fifth electronic switch and said sixth electronic switch, and
monitoring a reset request signal indicating a reset request and starting a reset phase in response to determining that said reset request signal indicates a reset request; and
during said reset phase:
for a first reset interval, closing said first, second, third, fourth, fifth and sixth electronic switches, and
for a second reset interval, opening said third and fourth electronic switches and keep closed said first, second, fifth and sixth electronic switches, and the start again said normal operation phase.
